(19) United States
(12) Patent Application Publication
(10) Pub. No.: US 2025/0149398 A1
(43) Pub. Date: May 8, 2025

(54) SEMICONDUCTOR PACKAGE

(71) Applicant: SAMSUNG ELECTRONICS CO., LTD., Suwon-si (KR)

(72) Inventor: Dawoon JUNG, Suwon-si (KR)

(73) Assignee: SAMSUNG ELECTRONICS CO., LTD., Suwon-si (KR)

(21) Appl. No.: 18/658,436

(22) Filed: May 8, 2024

(30) Foreign Application Priority Data
Nov. 7, 2023 (KR) 10-2023-0152793

(51) Int. Cl. H01L 23/367; H01L 23/00; H01L 23/31; H01L 23/48; H01L 25/065; H01L 25/10; H10B 80/00

(52) U.S. Cl. CPC H01L 23/367; H01L 23/3107; H01L 23/481; H01L 24/08; H01L 25/0657; H01L 25/105; H10B 80/00; H01L 2224/08145

(57) ABSTRACT

A semiconductor package includes: a buffer die; a plurality of semiconductor dies on the buffer die; a dummy die on the plurality of semiconductor dies; and a mold layer. The dummy die includes: a dummy substrate comprising a trench formed in a top surface of the dummy substrate, extended in a first direction and a second direction, and having a shape of checkerboard; and an oxide layer on a bottom surface of the dummy substrate. At least one of the plurality of semiconductor dies includes: a substrate, an upper passivation layer and a lower passivation layer. The oxide layer is in direct contact with the upper passivation layer of an uppermost one of the plurality of semiconductor dies. A level of a bottom surface of the trench is higher than a level of the bottom surface of the dummy substrate.

### CROSS-REFERENCE TO RELATED APPLICATION

This application is based on and claims priority under 35 U.S.C. § 119 to Korean Patent Application No. 10-2023-0152793, filed on Nov. 7, 2023, in the Korean Intellectual Property Office, the disclosure of which is incorporated by reference herein in its entirety.

### BACKGROUND

### 1. Field

The disclosure relates to a semiconductor package, and in particular, to a semiconductor package including a dummy die with a trench formed on a top surface of the dummy die.

A semiconductor package is configured to facilitate a use of an integrated circuit chip as a component in an electronic product. Conventionally, the semiconductor package includes a printed circuit board (PCB) and a semiconductor chip die, which is mounted on the PCB and is electrically connected to the PCB using bonding wires or bumps. With development of the electronic industry, many studies are being conducted to enhance reliability and durability of the semiconductor package.

### SUMMARY

Provided is a semiconductor package with enhanced durability and reliability.

According to an aspect of the disclosure, a semiconductor package includes: a buffer die; a plurality of semiconductor dies on the buffer die; a dummy die on the plurality of semiconductor dies; and a mold layer surrounding the buffer die, the plurality of semiconductor dies, and the dummy die, wherein the dummy die includes: a dummy substrate including a trench formed in a top surface of the dummy substrate, extended in a first direction and a second direction, and having a shape of checkerboard; and an oxide layer on a bottom surface of the dummy substrate, wherein at least one of the plurality of semiconductor dies includes: a substrate, an upper passivation layer on a top surface of the substrate, and a lower passivation layer on a bottom surface of the substrate, wherein the oxide layer is in direct contact with the upper passivation layer of an uppermost one of the plurality of semiconductor dies, and wherein a level of a bottom surface of the trench is higher than a level of the bottom surface of the dummy substrate.

According to an aspect of the disclosure, a semiconductor package includes: a buffer die; a plurality of memory dies on the buffer die; a dummy die on the plurality of memory dies; and a mold layer surrounding the buffer die, the plurality of memory dies, and the dummy die, wherein the buffer die includes: a first substrate; first upper conductive pads on a top surface of the first substrate; first lower conductive pads on a bottom surface of the first substrate; and a first penetration via penetrating the first substrate, wherein at least one of the plurality of memory dies includes: a second substrate; second upper conductive pads on a top surface of the second substrate; second lower conductive pads on a bottom surface of the second substrate; and a second penetration via penetrating the second substrate, wherein the dummy die includes: a third substrate including a trench formed in a top surface of the third substrate, extended in a first direction and a second direction, and having a shape of checkerboard; an oxide layer on a bottom surface of the third substrate; and a heat transfer member filling the trench, wherein the dummy die has a thickness ranging from about 55 μm to about 550 μm.

According to an aspect of the disclosure, a semiconductor package includes: a package substrate; an interposer substrate on the package substrate; a first semiconductor chip on the interposer substrate; and a second semiconductor chip on the interposer substrate, wherein the first semiconductor chip includes: a buffer die; a plurality of semiconductor dies on the buffer die; a dummy die on the plurality of semiconductor dies; and a mold layer surrounding the buffer die, the plurality of semiconductor dies, and the dummy die, wherein the dummy die includes: a dummy substrate including a trench formed in a top surface of the dummy substrate, extended in a first direction and a second direction, and having a shape of checkerboard; a heat transfer member filling the trench; and an oxide layer on a bottom surface of the dummy substrate, wherein at least one of the plurality of semiconductor dies includes a substrate, wherein a level of a bottom surface of the trench is higher than a level of the bottom surface of the dummy substrate, and wherein the bottom surface of the trench is flat.

### BRIEF DESCRIPTION OF DRAWINGS

The above and other aspects, features, and advantages of certain embodiments of the disclosure will be more apparent from the following description taken in conjunction with the accompanying drawings, in which:

FIG. 1A is a plan view illustrating a semiconductor package according to an embodiment of the disclosure;

FIG. 1B is a sectional view taken along a line A-A′ of FIG. 1A;

FIG. 2 is a sectional view illustrating a semiconductor package according to an embodiment of the disclosure;

FIG. 3 is a sectional view illustrating a semiconductor package according to an embodiment of the disclosure;

FIG. 4A is a plan view illustrating a wafer according to an embodiment of the disclosure;

FIG. 4B is a plan view illustrating a process of fabricating a dummy die of FIG. 1B, according to an embodiment of the disclosure. FIG. 4B is an enlarged plan view illustrating a portion ‘P1’ of FIG. 4A.

FIG. 4C is a sectional view illustrating a process of fabricating the dummy die of FIG. 1B, according to an embodiment of the disclosure. FIG. 4C is a sectional view taken along a line B-B′ of FIG. 4B;

FIG. 4D is a sectional view illustrating a dummy die according to an embodiment of the disclosure;

FIGS. 5A to 5I are sectional views illustrating a process of fabricating the semiconductor package of FIG. 1B, according to an embodiment of the disclosure;

FIGS. 6A and 6B are sectional views illustrating a process of fabricating the semiconductor package of FIG. 1B, according to an embodiment of the disclosure. FIGS. 6A and 6B is an enlarged plan view illustrating a portion ‘P2’ of FIG. 5B;

FIG. 7 is a sectional view illustrating a semiconductor package according to an embodiment of the disclosure; and

FIG. 8 is a sectional view illustrating a semiconductor package according to an embodiment of the disclosure.

### DETAILED DESCRIPTION

Example embodiments of the disclosures will now be described more fully with reference to the accompanying drawings, in which example embodiments are shown.

The description merely illustrates the principles of the disclosure. Those skilled in the art will be able to devise one or more arrangements that, although not explicitly described herein, embody the principles of the disclosure. Furthermore, all examples recited herein are principally intended expressly to be only for explanatory purposes to help the reader in understanding the principles of the disclosure and the concepts contributed by the inventor to furthering the art and are to be construed as being without limitation to such specifically recited examples and conditions. Moreover, all statements herein reciting principles, aspects, and embodiments of the disclosure, as well as specific examples thereof, are intended to encompass equivalents thereof.

Terms used in the disclosure are used only to describe a specific embodiment, and may not be intended to limit the scope of another embodiment. A singular expression may include a plural expression unless it is clearly meant differently in the context. The terms used herein, including a technical or scientific term, may have the same meaning as generally understood by a person having ordinary knowledge in the technical field described in the present disclosure. Terms defined in a general dictionary among the terms used in the present disclosure may be interpreted with the same or similar meaning as a contextual meaning of related technology, and unless clearly defined in the present disclosure, it is not interpreted in an ideal or excessively formal meaning. In some cases, even terms defined in the disclosure cannot be interpreted to exclude embodiments of the present disclosure.

In one or more embodiments of the disclosure described below, a hardware approach is described as an example. However, since the one or more embodiments of the disclosure include technology that uses both hardware and software, the various embodiments of the present disclosure do not exclude a software-based approach.

In addition, in the disclosure, in order to determine whether a specific condition is satisfied or fulfilled, an expression of more than or less than may be used, but this is only a description for expressing an example, and does not exclude description of more than or equal to or less than or equal to. A condition described as ‘more than or equal to’ may be replaced with ‘more than’, a condition described as ‘less than or equal to’ may be replaced with ‘less than’, and a condition described as ‘more than or equal to and less than’ may be replaced with ‘more than and less than or equal to’.

The terms “include” and “comprise”, and the derivatives thereof refer to inclusion without limitation. The term “or” is an inclusive term meaning “and/or”. The phrase “at least one of,” when used with a list of items, means that different combinations of one or more of the listed items may be used, and only one item in the list may be needed. For example, “at least one of A, B, and C” includes any of the following combinations: A, B, C, A and B, A and C, B and C, and A and B and C, and any variations thereof. As an additional example, the expression “at least one of a, b, or c” may indicate only a, only b, only c, both a and b, both a and c, both b and c, all of a, b, and c, or variations thereof. Similarly, the term “set” means one or more. Accordingly, the set of items may be a single item or a collection of two or more items.

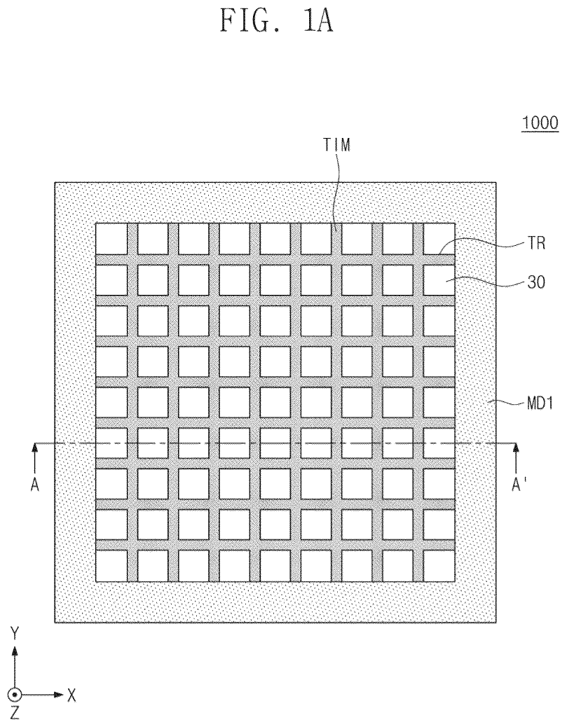

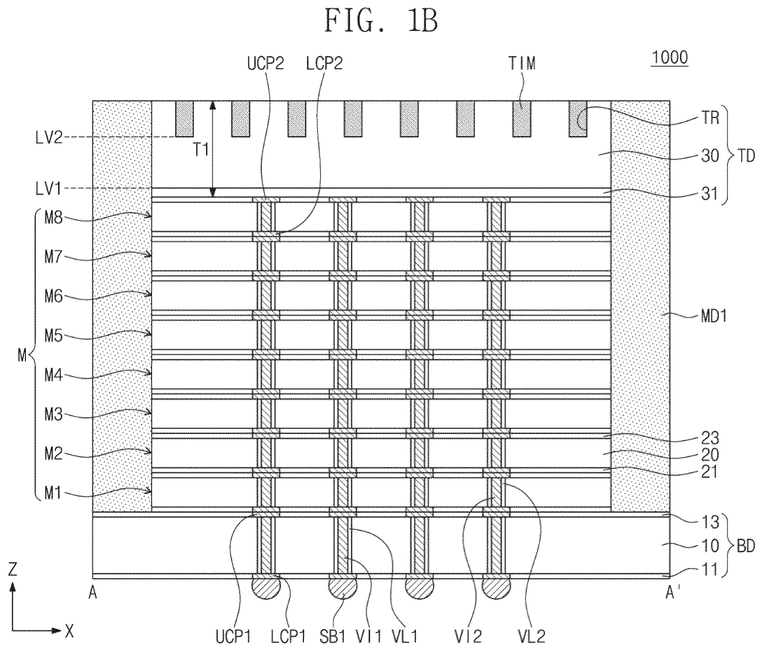

FIG. 1A is a plan view illustrating a semiconductor package according to an embodiment of the disclosure. FIG. 1B is a sectional view taken along a line A-A′ of FIG. 1A.

Referring to FIGS. 1A and 1B, a semiconductor package 1000 in the present embodiment may include a buffer die BD, memory dies M, a dummy die TD, and a first mold layer MD1. The term ‘die’ may be called ‘chip’.

In an embodiment, the buffer die BD may be a chip with a logic circuit. The buffer die BD may be used as an interface circuit between the memory dies M and an external controller. The buffer die BD may be configured to receive commands, data, and/or signals, which are transmitted from the external controller, and to transmit the received commands, data, and/or signals to the memory dies M. Alternatively, the buffer die BD may be or correspond to a memory chip, such as a flash memory chip, a dynamic random access memory (DRAM) chip, a static random access memory (SRAM) chip, an electrically erasable programmable read-only memory (EEPROM) chip, a phase change random access memory (PRAM) chip, a magnetoresistive random access memory (MRAM chip), and a resistive random access memory (ReRAM) chip. In an embodiment, the buffer die BD may be an interposer die without a transistor.

The memory dies M may include first to eighth memory dies M1 to M8. As shown in FIG. 1B, the first to eighth memory dies M1 to M8 may be sequentially stacked on the buffer die BD. The first to eighth memory dies M1 to M8 may be a chip that is different from the buffer die BD. The first to eighth memory dies M1 to M8 may be memory chips of the same kind. In an embodiment, the memory chip may be a FLASH memory chip, a DRAM chip, an SRAM chip, an EEPROM chip, a PRAM chip, an MRAM chip, or a ReRAM chip. A width of the buffer die BD may be larger than widths of the first to eighth memory dies M1 to M8.

The embodiment illustrates a structure, in which one logic circuit chip and eight memory chips are stacked, but the stacking numbers of the logic circuit chip and the memory chips are not limited to this embodiment and are variously changed. For example, four, twelve, or more memory chips may be stacked. The semiconductor package 1000 may have a high bandwidth memory (HBM) chip structure. In an embodiment, the semiconductor package 1000 may be a semiconductor package having a die-to-die bonding structure, a die-to-wafer bonding structure, or a wafer-on-wafer bonding structure.

The buffer die BD may include a first substrate 10. The first substrate 10 may be a semiconductor wafer, which is formed of a semiconductor material (e.g., silicon), a silicon-on-insulator (SOI) wafer, and/or an insulating wafer. In an embodiment, an integrated circuit (including a transistor and an internal interconnection line) and an interlayer insulating layer surrounding the integrated circuit may be disposed on the first substrate 10.

The buffer die BD may include a first penetration via VI1. The first penetration via VI1 may be provided to penetrate the first substrate 10. A first penetration insulating layer VL1 may be interposed between the first penetration via VI1 and the first substrate 10. The first penetration via VI1 may be formed of or include a metallic material (e.g., copper, aluminum, and tungsten). The first penetration insulating layer VL1 may be formed of or include at least one of silicon oxide, silicon nitride, or silicon oxynitride and may have a single-layered structure or a multi-layered structure. The first penetration insulating layer VL1 may include an air gap region.

First upper conductive pads UCP1 may be disposed on a top surface of the first substrate 10. The first upper conductive pads UCP1 may be connected to the first penetration vias VI1, respectively. First lower conductive pads LCP1 may be disposed on a bottom surface of the first substrate 10. The first lower conductive pads LCP1 may be connected to the first upper conductive pads UCP1 through the first penetration vias VI1. For example, the first upper conductive pads UCP1 and the first lower conductive pads LCP1 may be formed of or include copper. However, embodiments of the disclosure are not limited to this example. In an embodiment, the first upper conductive pads UCP1 and the first lower conductive pads LCP1 may be formed of or include at least one of metallic materials (e.g., gold, nickel, aluminum, and tungsten).

The first lower conductive pads LCP1 may be bonded to first outer connection members SB1, respectively. The outer connection members SB1 may include at least one of conductive bumps or solder balls. The outer connection members SB1 may be formed of or include at least one of metallic materials (e.g., copper, nickel, tin, and silver).

As shown in FIG. 1B, a first upper passivation layer 13 may be disposed on the top surface of the first substrate 10. The first upper passivation layer 13 may surround the first upper conductive pads UCP1 and the top surface of the first substrate 10. A first lower passivation layer 11 may be disposed on the bottom surface of the first substrate 10. The first lower passivation layer 11 may surround the first lower conductive pads LCP1. The passivation layers (the first lower passivation layer 11 and the first upper passivation layer 13) may be formed of or include at least one of silicon oxide, silicon nitride, and silicon carbonitride and may have a single-layered structure or multi-layered structure.

Each (at least one) of the first to eighth memory dies M1 to M8 may include a second substrate 20. The second substrate 20 may be a semiconductor wafer, which is formed of a semiconductor material (e.g., silicon), a silicon-on-insulator (SOI) wafer, and/or an insulating wafer. In an embodiment, an integrated circuit (including a transistor and an internal interconnection line) and an interlayer insulating layer surrounding the integrated circuit may be disposed on the second substrate 20. The memory die may be referred to as a ‘semiconductor die’. The second substrate may be referred to as a ‘semiconductor substrate’.

Each (or at least one) of the first to eighth memory dies M1 to M8 may include a second penetration via VI2. The second penetration via VI2 may be provided to penetrate the second substrate 20. The second penetration via VI2 may be connected to the first penetration via VI1 of the buffer die BD. A second penetration insulating layer VL2 may be interposed between the second penetration via VI2 and the second substrate 20. The second penetration via VI2 may be formed of or include a metallic material (e.g., copper, aluminum, and tungsten). The second penetration insulating layer VL2 may be formed of or include at least one of silicon oxide, silicon nitride, or silicon oxynitride and may have a single-layered structure or a multi-layered structure. The second penetration insulating layer VL2 may include an air gap region.

Second upper conductive pads UCP2 may be disposed on a top surface of the second substrate 20. The second upper conductive pads UCP2 may be connected to the second penetration vias VI2, respectively. Second lower conductive pads LCP2 may be disposed on a bottom surface of the second substrate 20. The second lower conductive pads LCP2 may be connected to the second upper conductive pads UCP2 through the second penetration vias VI2. For example, the second upper conductive pads UCP2 and the second lower conductive pads LCP2 may be formed of or include copper. However, embodiments of the disclosure are not limited to this example, and in an embodiment, the second upper conductive pads UCP2 and the second lower conductive pads LCP2 may be formed of or include at least one of metallic materials (e.g., gold, nickel, aluminum, and tungsten).

A second upper passivation layer 23 may be disposed on the top surface of the second substrate 20. The second upper passivation layer 23 may surround the second upper conductive pads UCP2 and the top surface of the second substrate 20. A second lower passivation layer 21 may be disposed on the bottom surface of the second substrate 20. The second lower passivation layer 21 may surround the second lower conductive pads LCP2. Each (or at least one) of the passivation layers (the second lower passivation layer 21 and the second upper passivation layer 23) may be formed of or include at least one of silicon oxide, silicon nitride, silicon carbonitride and may have a single-layered structure or a multi-layered structure.

As shown in FIG. 1B, the first upper conductive pads UCP1 of the buffer die BD may be in direct contact with the second lower conductive pads LCP2 of the first memory die M1, respectively. The first upper conductive pads UCP1 and the second lower conductive pads LCP2 may be formed of or include the same material. The first upper conductive pads UCP1 and the second lower conductive pads LCP2 may be provided such that adjacent ones of them (the first upper conductive pads UCP1 and the second lower conductive pads LCP2) are bonded to each other to form a single object. The first upper passivation layer 13 of the buffer die BD may be in direct contact with the second lower passivation layer 21 of the first memory die M1.

Adjacent ones of the first to eighth memory dies M1 to M8 may be provided such that the second upper conductive pads UCP2 of a lower die of them (the first to eighth memory dies M1 to M8) are in contact with the second lower conductive pads LCP2 of an upper die of them (the first to eighth memory dies M1 to M8), respectively. The second upper conductive pads UCP2 and the second lower conductive pads LCP2 may be formed of or include the same material. The second upper conductive pads UCP2 and the second lower conductive pads LCP2 may be provided such that adjacent ones of them (the second upper conductive pads UCP2 and the second lower conductive pads LCP2) are bonded to each other to form a single object. In an embodiment, the second upper conductive pads UCP2 of the first memory die M1 may be in contact with the second lower conductive pads LCP2 of the second memory die M2.

Adjacent ones of the first to eighth memory dies M1 to M8 may be provided such that the second upper passivation layer 23 of a lower die of them (the first to eighth memory dies M1 to M8) are in direct contact with the second lower passivation layer 21 of an upper die of them (the first to eighth memory dies M1 to M8), respectively. For example, the second upper passivation layer 23 of the first memory die M1 may be in direct contact with the second lower passivation layer 21 of the second memory die M2.

Thus, the buffer die BD and the first memory die M1 may form a structure by a direct bonding process or a hybrid copper bonding process, and the first to eighth memory dies M1 to M8 may form a structure by the direct bonding process or the hybrid copper bonding process.

The dummy die TD may be disposed on the memory dies M. The dummy die TD may include a third substrate 30. The third substrate 30 may be a semiconductor wafer, which is formed of a semiconductor material (e.g., silicon), a silicon-on-insulator (SOI) wafer, and/or an insulating wafer. The third substrate may be referred to as a ‘dummy substrate.’ In an embodiment, the dummy die TD may not include an integrated circuit. In an embodiment, the dummy die TD may have a first thickness T1 ranging from 55 μm to 550 μm.

As shown in FIG. 1A, the third substrate 30 may include a trench TR, which is formed in a top surface of the third substrate 30 and is extended in a first direction X and a second direction Y to form, for example, a shape of checkerboard. Thus, the top surface of the third substrate 30 may have an uneven structure. A first level LV1 of a bottom surface of the trench TR may be higher than a second level LV2 of a bottom surface of the third substrate 30. The bottom surface of the trench TR may have a flat shape. The trench TR may be filled with a heat transfer member TIM. In an embodiment, the heat transfer member TIM may include a thermosetting resin layer. The heat transfer member TIM may further include filler particles, which are dispersed in the thermosetting resin layer. The filler particles may be formed of or include at least one of silica, alumina, zinc oxide, or boron nitride. Since the trench TR is filled with the heat transfer member TIM having a higher thermal conductivity than the third substrate 30, it may be possible to effectively exhaust heat generated during the operation of the semiconductor package 1000. Thus, the semiconductor package 1000 may be provided to have high reliability.

The dummy die TD may further include an oxide layer 31, which is disposed on the bottom surface of the third substrate 30. For example, the oxide layer 31 may be formed of or include silicon oxide (e.g., SiO₂). The oxide layer 31 may be in direct contact with the second upper passivation layer 23 of the eighth memory die M8.

The dummy die TD may be used as a reinforcing element, a stiffener, or a heat spreader. Also, the dummy die TD may be referred to as a reinforcing element, a stiffener, or a heat spreader.

The first mold layer MD1 may be formed on the side surfaces of the first to eighth memory dies M1 to M8, the side surface of the dummy die TD, and the top surface of the buffer die BD. In an embodiment, the first mold layer MD1 may be formed of or include an insulating resin (e.g., an epoxy-based molding compound (EMC)). The first mold layer MD1 may further include fillers, which are dispersed in the insulating resin. In an embodiment, the filler may be formed of or include silicon oxide (SiO₂).

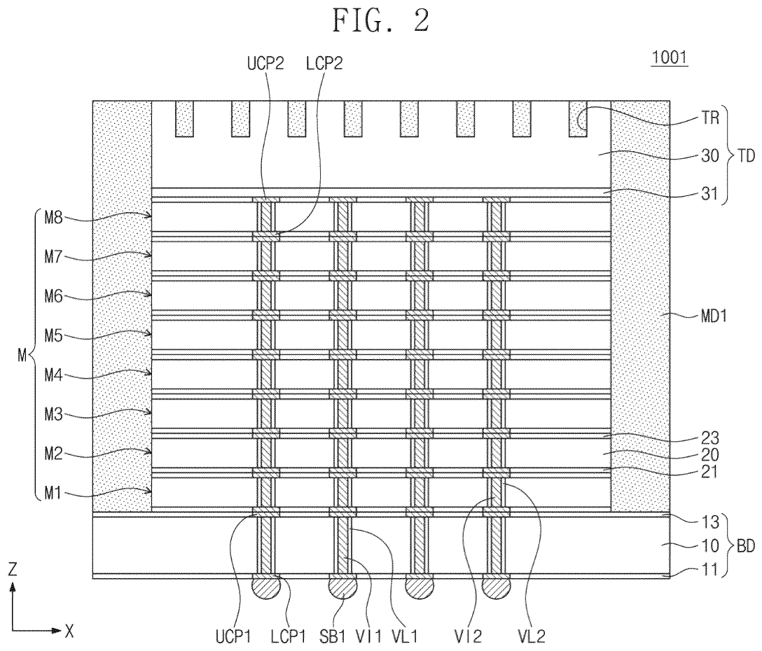

FIG. 2 is a sectional view illustrating a semiconductor package according to an embodiment of the disclosure.

Referring to FIG. 2, a semiconductor package 1001 may have a structure that is similar to that of FIG. 1B, but the trench TR may be filled with the first mold layer MD1. For this structure, it may be possible to omit a process of filling the trench TR with an additional material and thereby to reduce a fabrication cost. Except for the above features, the semiconductor package may be configured to have substantially the same or similar features as the semiconductor package described with reference to FIGS. 1A and 1B.

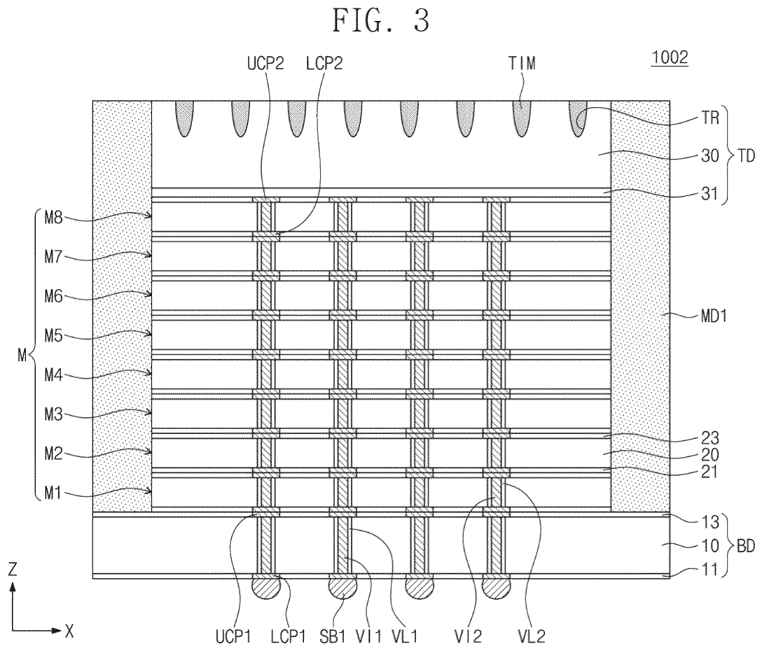

FIG. 3 is a sectional view illustrating a semiconductor package according to an embodiment of the disclosure.

Referring to FIG. 3, a semiconductor package 1002 may have a structure that is similar to that of FIG. 1B, but the trench TR may be provided to have a concave bottom surface. Except for the above features, the semiconductor package may be configured to have substantially the same or similar features as the semiconductor package described with reference to FIGS. 1A and 1B.

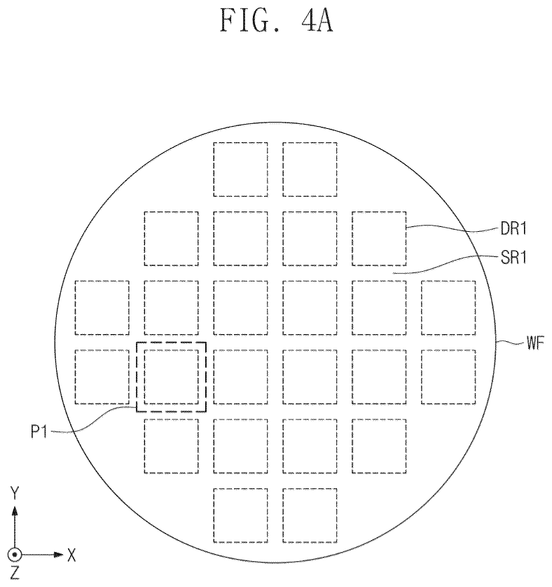

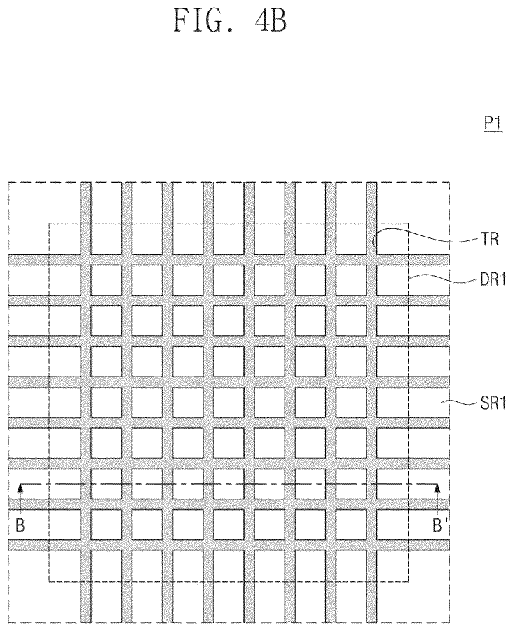

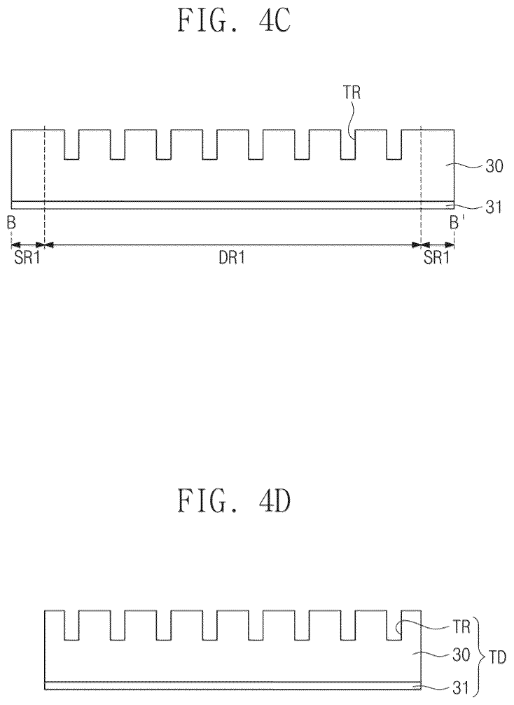

FIG. 4A is a plan view illustrating a wafer according to an embodiment of the disclosure. FIG. 4B is a plan view illustrating a process of fabricating a dummy die of FIG. 1B, according to an embodiment of the disclosure. Specifically, FIG. 4B is an enlarged plan view illustrating a portion ‘P1’ of FIG. 4A. FIG. 4C is a sectional view illustrating a process of fabricating the dummy die of FIG. 1B, according to an embodiment of the disclosure. FIG. 4C is a sectional view taken along a line B-B′ of FIG. 4B. FIG. 4D is a sectional view illustrating a dummy die according to an embodiment of the disclosure.

Referring to FIG. 4A, a plurality of first chip regions DR1 may be arranged on a wafer WF. Each (or at least one) of the first chip regions DR1 may correspond to the dummy die TD described with reference to FIGS. 1A and 1B. A first separation region SR1 may be disposed between the first chip regions DR1. The first separation region SR1 may be a scribe lane region. The wafer WF may correspond to the third substrate 30 of FIGS. 4C and 4D.

Referring to FIG. 4B, a first sawing process using a blade may be performed to saw the first chip regions DR1 and the first separation region SR1 in the first direction X and the second direction Y and to form the trench TR of a checkerboard shape in an upper portion of the wafer WF. However, embodiments of the disclosure are not limited to this example, and the trench TR may be formed using various methods (e.g., a plasma etching method, a sputter etching method, and a reactive ion etching method). In addition, the trench TR may be formed in various shapes, when viewed in a plan view; for example, the trench TR may be formed to cross the first chip regions DR1 in one of the first direction X and the second direction Y or in a diagonal direction.

Referring to FIGS. 4B and 4C, the trench TR may be formed in the first chip regions DR1 of the third substrate 30 to have the checkerboard shape. In an embodiment, before the formation of the trench TR, the oxide layer 31 may be formed on the bottom surface of the third substrate 30.

Referring to FIG. 4D, a second sawing process using a blade may be performed to remove the first separation region SR1 and separate a plurality of dummy dies TD from each other. As a result, the dummy die TD may be formed to have one of the structures described with reference to FIGS. 1A to 3.

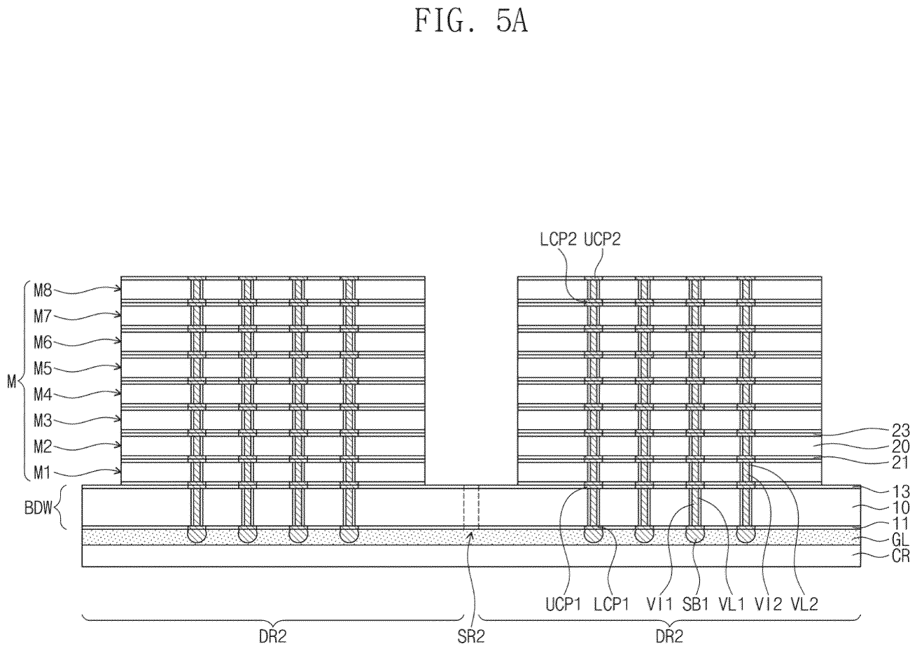

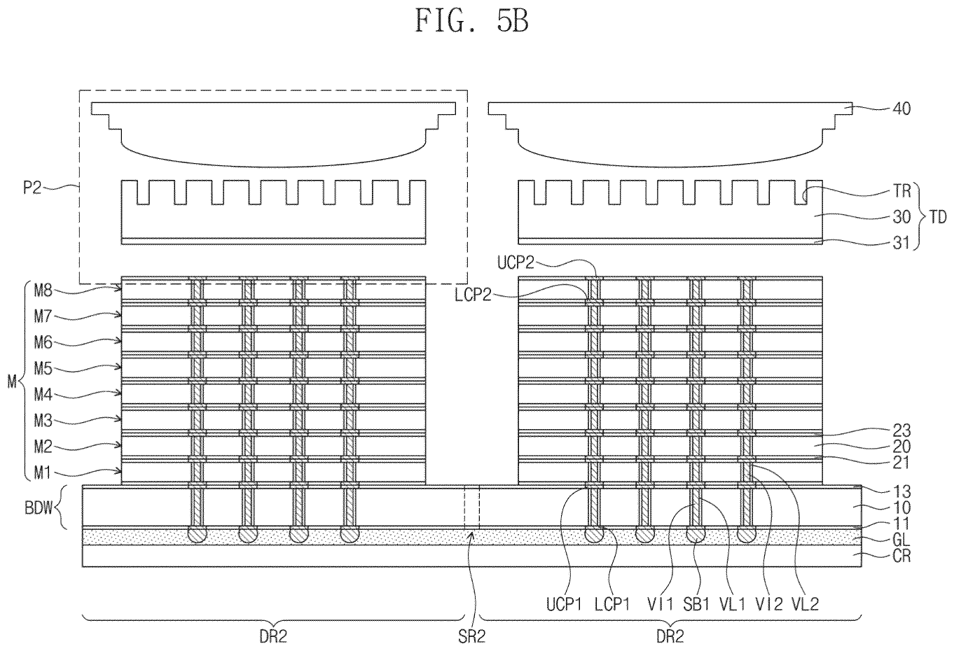

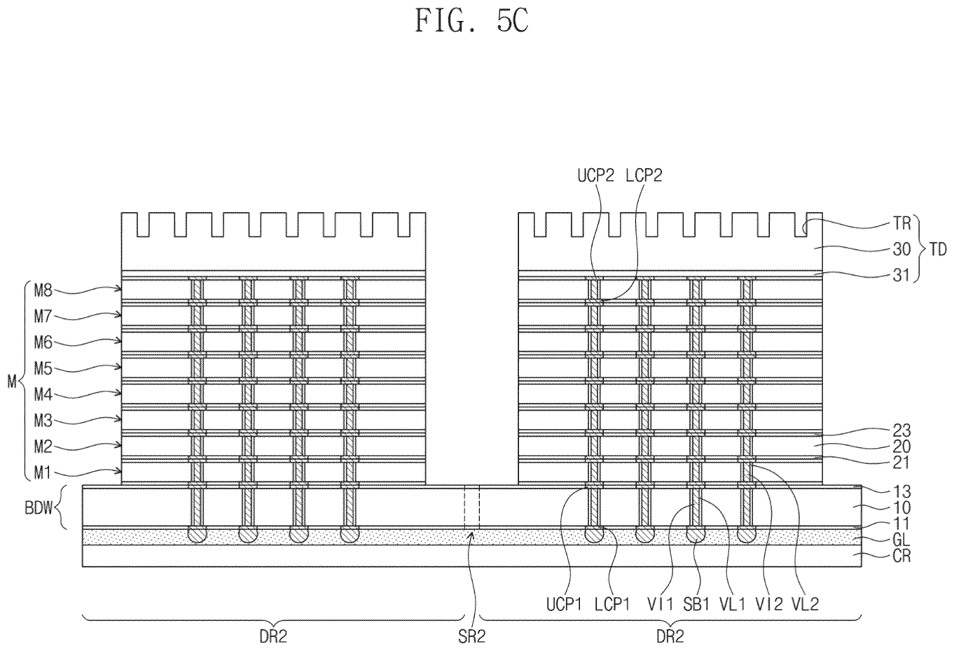

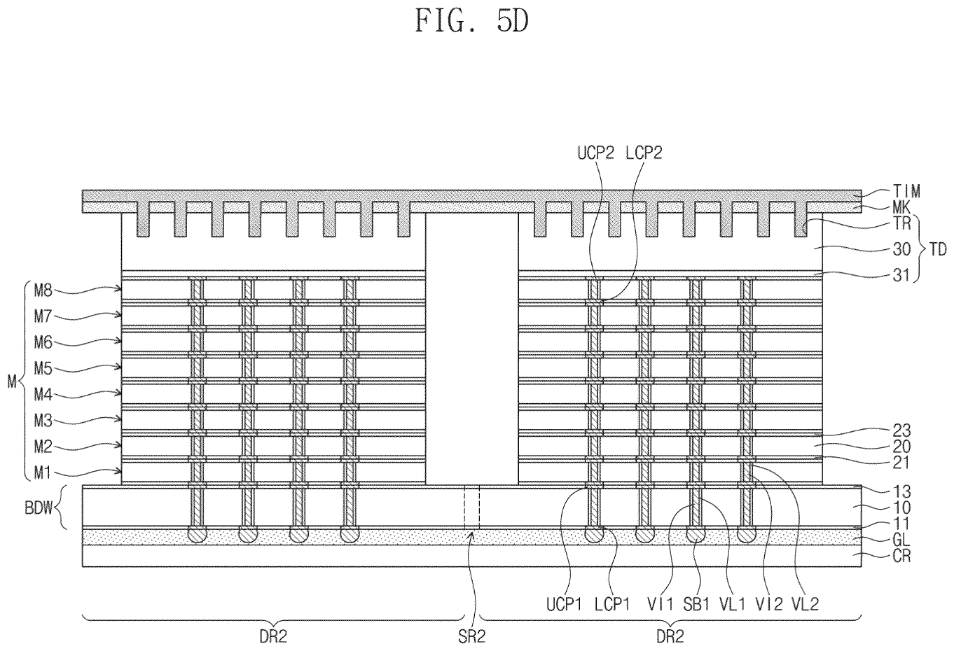

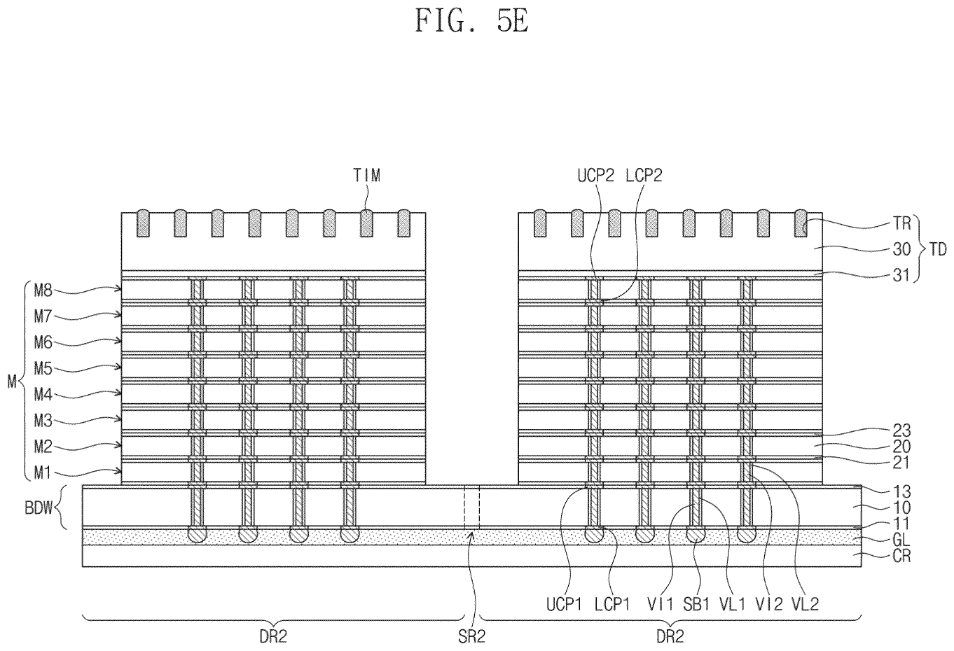

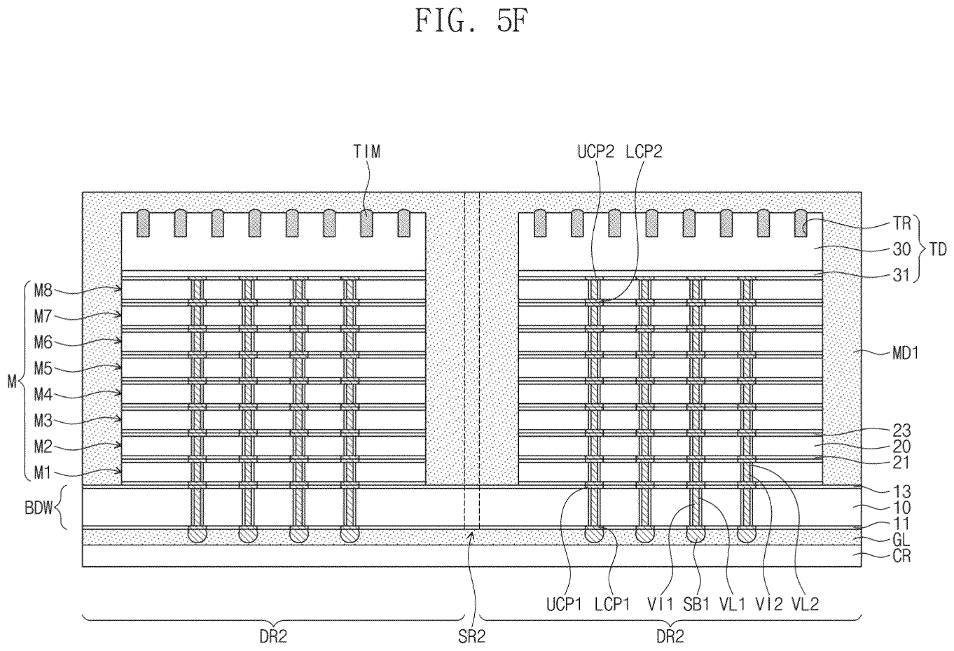

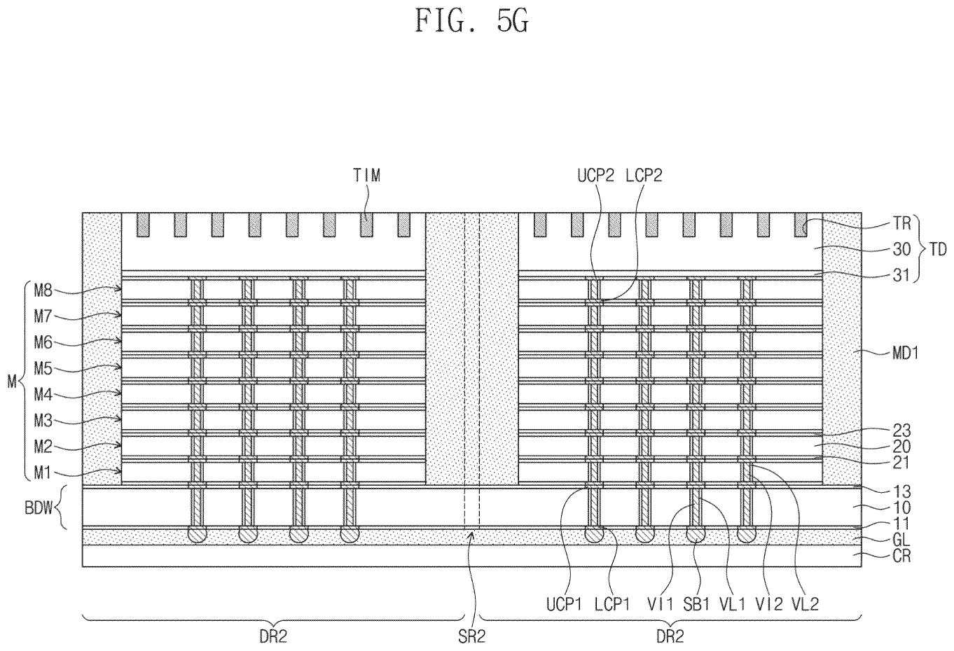

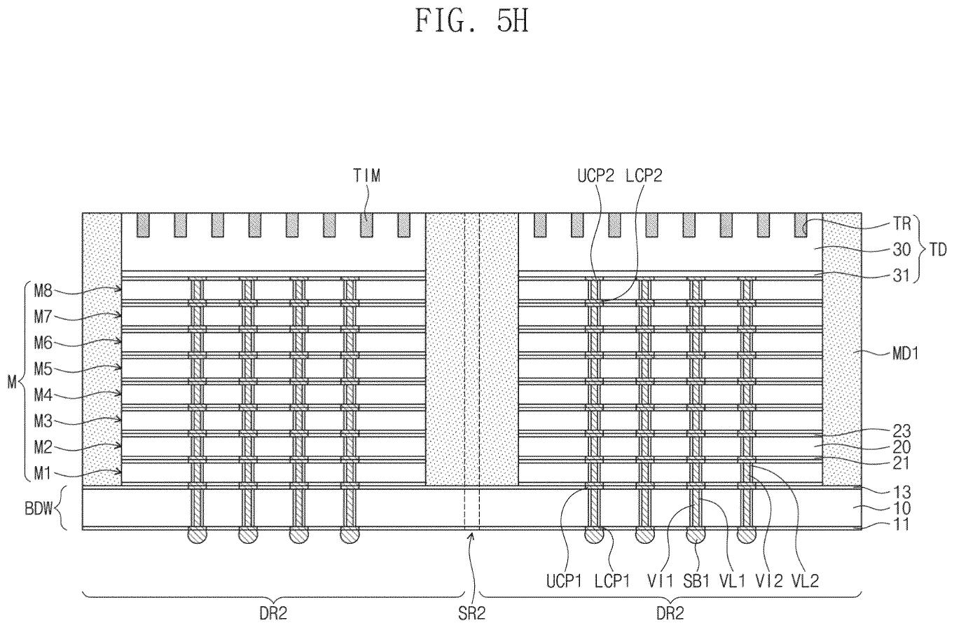

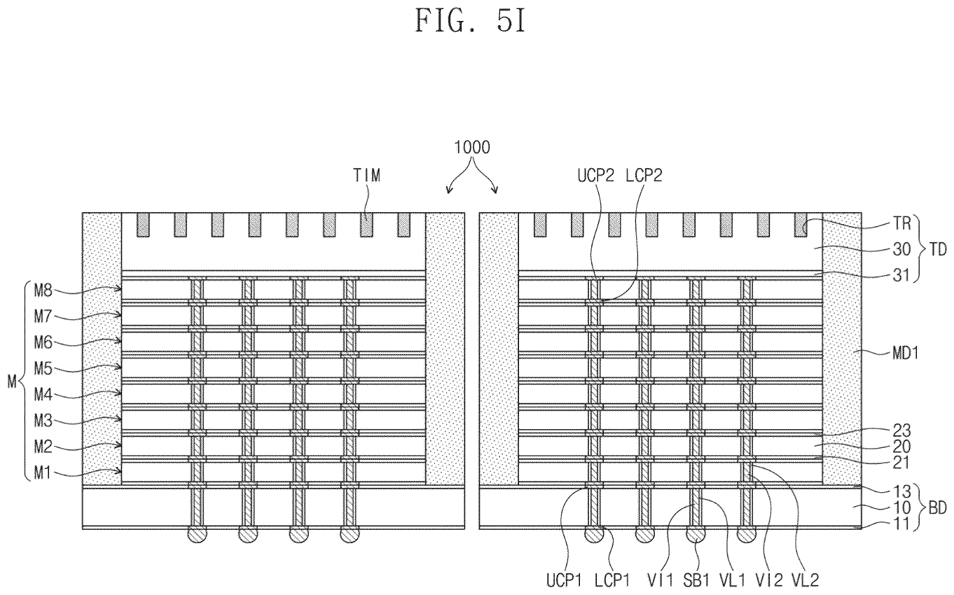

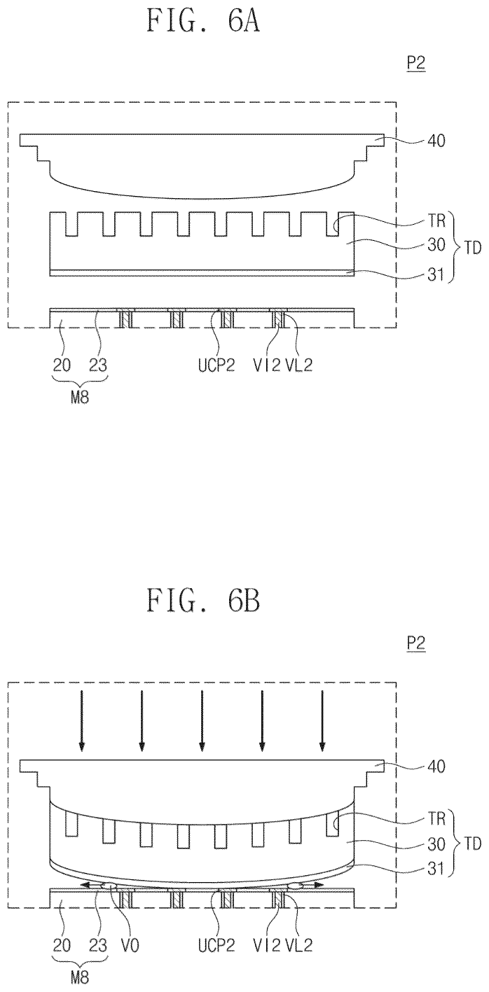

FIGS. 5A to 5I are sectional views illustrating a process of fabricating the semiconductor package of FIG. 1B, according to an embodiment of the disclosure. FIGS. 6A and 6B are sectional views illustrating a process of fabricating the semiconductor package of FIG. 1B, according to an embodiment of the disclosure. FIGS. 6A and 6B are enlarged sectional views illustrating a portion ‘P2’ of FIG. 5B. Descriptions of previously described elements may be omitted.

Referring to FIG. 5A, a wafer for a buffer die (hereinafter, a buffer wafer BDW) may be prepared. The buffer wafer BDW may have a plurality of second chip regions DR2 and a second separation region SR2 therebetween. Each (or at least one) of the second chip regions DR2 of the buffer wafer BDW may have substantially the same structure as the buffer die BD described with reference to FIGS. 1A and 1B. The second separation region SR2 may be a scribe lane region. The buffer wafer BDW may include the first substrate 10. The first penetration via VI1 and the first penetration insulating layer VL1 may be formed to penetrate the second chip regions DR2 of the first substrate 10. The first lower conductive pads LCP1 and the first lower passivation layer 11 surrounding them (the first lower conductive pads LCP1) may be formed on the bottom surface of the first substrate 10. The first outer connection members SB1 may be connected to the first lower conductive pads LCP1. The buffer wafer BDW may be disposed such that the first outer connection members SB1 are placed at a lower level in a vertical direction, and then, the buffer wafer BDW may be bonded to a carrier substrate CR using a carrier adhesive layer GL. The carrier adhesive layer GL may include an adhesive resin, a thermosetting resin, a thermoplastic resin, or a photo-curable resin.

A back-grinding process may be performed on the top surface of the first substrate 10, and then, the first upper conductive pads UCP1 and the first upper passivation layer 13 surrounding them (the first upper conductive pads UCP1) may be formed on the top surface of the first substrate 10. In an embodiment, an integrated circuit (including a transistor and an internal interconnection line) may be formed on the first substrate 10. An interlayer insulating layer may be formed on the bottom surface of the first substrate 10 to surround the integrated circuit.

Next, the memory dies M may be prepared. The memory dies M may include the first to eighth memory dies M1 to M8. Each (or at least one) of the first to eighth memory dies M1 to M8 may include the second substrate 20, an integrated circuit, an interlayer insulating layer, the second penetration via VI2, the second penetration insulating layer VL2, the second upper conductive pads UCP2, the second lower conductive pads LCP2, the second upper passivation layer 23, and the second lower passivation layer 21, which are formed using substantially the same method described above. Next, a sawing process may be performed to form the first to eighth memory dies M1 to M8 of the same size.

The first to eighth memory dies M1 to M8 may be stacked on the second chip regions DR2 of the buffer wafer BDW. The first memory die M1 may be disposed such that an active surface of the first memory die M1 faces the buffer wafer BDW. The first memory die M1 may be placed on the buffer wafer BDW such that the second lower passivation layer 21 and the second lower conductive pads LCP2 are in contact with the first upper passivation layer 13 and the first upper conductive pads UCP1, respectively. The second memory die M2 may be disposed such that an active surface of the second memory die M2 faces the first memory die M1. In an embodiment, the second lower passivation layer 21 and the second lower conductive pads LCP2 of the second memory die M2 are in contact with the second upper passivation layer 23 and the second upper conductive pads UCP2 of the first memory die M1, respectively. The first to eighth memory dies M1 to M8 may be stacked by the same method.

Referring to FIGS. 5B, 5C, 6A, and 6B, the dummy die TD may be placed on the eighth memory die M8 such that the oxide layer 31 of the dummy die TD is in contact with the second upper passivation layer 23 of the eighth memory die M8, which is the uppermost one of the memory dies M. A thermo-compression process may be performed using a bonding tool 40. Accordingly, the first to eighth memory dies M1 to M8 and the dummy die TD on the buffer wafer BDW may be bonded to each other at the same time. Here, the buffer wafer BDW and the first memory die M1 may be directly bonded to each other by the first upper conductive pads UCP1 and the second lower conductive pads LCP2. An inorganic insulating layer (e.g., a silicon oxide layer) may be formed between the passivation layers 13 and 21, which are respectively provided in the buffer wafer BDW and the first memory die M1. The second upper conductive pads UCP2 and the second lower conductive pads LCP2, which are respectively included in adjacent ones of the first to eighth memory dies M1 to M8, may be directly bonded to each other. An inorganic insulating layer (e.g., a silicon oxide layer) may be formed between the passivation layers (the second lower passivation layer 21 and the second upper passivation layer 23). The second upper passivation layer 23 of the eighth memory die M8 may be bonded to the oxide layer 31 of the dummy die TD in a direct-bonding manner. An inorganic insulating layer (e.g., a silicon oxide layer) may be formed between the oxide layer 31 of the dummy die TD and the second upper passivation layer 23 of the eighth memory die M8.

Since the trench TR is formed in the top surface of the third substrate 30 of the dummy die TD, the third substrate 30 may have a lowered stiffness and thus may be easily deformed during the thermo-compression process. In the case where, as shown in FIG. 6B, a pressure is exerted on the dummy die TD by the bonding tool 40, the third substrate 30 may be bent to have a shape corresponding to a curved bottom surface of the bonding tool 40. The bonding between the dummy die TD and the eighth memory die M8 may start at a center portion of the dummy die TD and may be extended to an edge portion of the dummy die TD. As a result, the dummy die TD may be bonded more tightly or closer to the eighth memory die M8, as shown in FIG. 5C.

In an embodiment, to enhance the reliability of the semiconductor package, it may be required for the dummy die TD to have a thickness of 55 μm or more. However, in the case where the thickness of the dummy die TD is larger than 55 μm, voids VO may be formed between the dummy die TD and the eighth memory die M8. By contrast, according to an embodiment of the disclosure, due to the trench TR formed in the dummy die TD, the dummy die TD may be in close contact with the eighth memory die M8, and in this case, it may be possible to prevent the voids VO from being formed between the eighth memory die M8 and the dummy die TD, even when the thickness of the dummy die TD is larger than 55 μm. Thus, it may be possible to enhance the durability and reliability of the semiconductor package 1000.

Referring to FIG. 5D, a mask pattern MK may be formed on the third substrate 30 so that the heat transfer member TIM fills the trench TR. A dispensing process may be performed to form the heat transfer member TIM, which fills the trench TR, on the mask pattern MK.

Referring to FIG. 5E, the heat transfer member TIM on the mask pattern MK may be removed. A curing process may be performed on the heat transfer member TIM in the trench TR. Then, the mask pattern MK may be removed to expose the dummy die TD. The heat transfer member TIM may include a protruding portion that is extended to a level higher than a top surface of the dummy die TD. The top surface of the dummy die TD may be convex.

Referring to FIG. 5F, a molding process may be performed to form the first mold layer MD1 on the top surface of the buffer die BD as well as the first to eighth memory dies M1 to M8 and the dummy die TD.

Referring to FIG. 5G, a grinding process may be performed to partially remove the first mold layer MD1, the heat transfer member TIM, and the third substrate 30. Accordingly, the eighth memory die M8, the heat transfer member TIM, and the first mold layer MD1 may be formed to have top surfaces that are coplanar with each other.

Referring to FIG. 5H, the buffer wafer BDW may be detached from the carrier adhesive layer GL.

Referring to FIG. 5I, a dicing process may be performed to remove the second separation region SR2 and form a plurality of semiconductor packages 1000. As a result, the semiconductor packages 1000 may be formed to have the same structure as FIG. 1B.

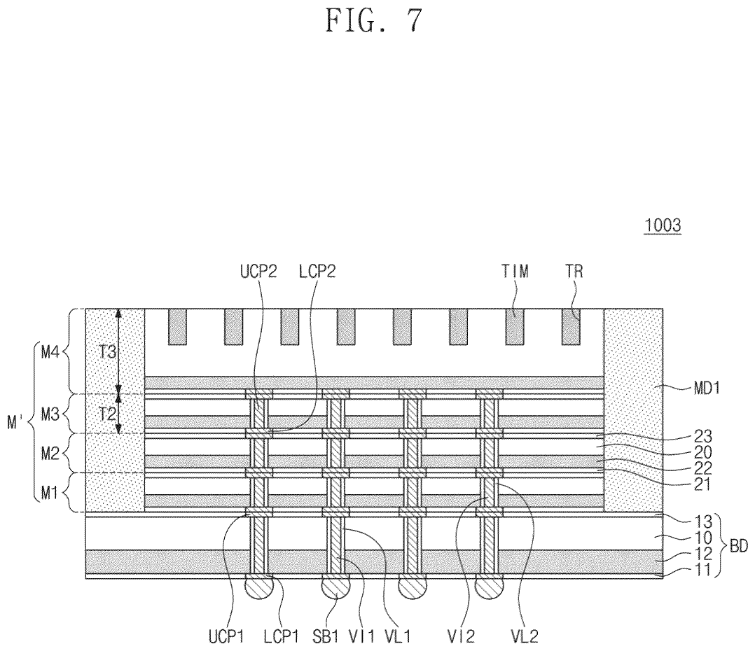

FIG. 7 is a sectional view illustrating a semiconductor package according to an embodiment of the disclosure.

Referring to FIG. 7, a semiconductor package 1003 may be a structure, which is similar to that of FIG. 1B but includes four stacked memory dies M′. For example, the memory dies M′ may include first to fourth memory dies M1 to M4. A first interlayer insulating layer 12 may be disposed on the bottom surface of the first substrate 10 of the buffer die BD. Second interlayer insulating layers 22 may be formed on bottom surfaces of the second substrates 20 of the first to fourth memory dies M1 to M4, respectively. The second substrate 20 of the fourth memory die M4, which is the uppermost one of the memory dies M′, may have the trench TR formed to penetrate a top surface of fourth memory die M4, as shown in FIGS. 1A to 3. In an embodiment, an integrated circuit including a transistor and an internal interconnection line may be formed on the bottom surface of each (or at least one) of the first substrate 10 and the second substrate 20. The first to third memory dies M1 to M3 may have a same second thickness T2. The fourth memory die M4 may have a third thickness T3 that is larger than the second thickness T2. Except for the above features, the semiconductor package may be configured to have substantially the same features as one of the semiconductor packages described with reference to FIGS. 1A to 6B.

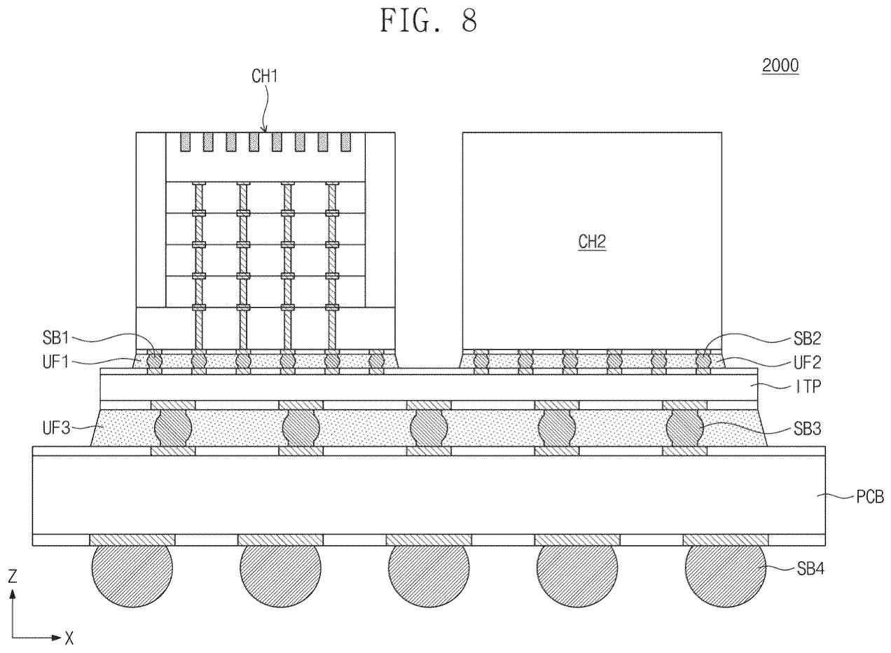

FIG. 8 is a sectional view illustrating a semiconductor package according to an embodiment of the disclosure.

Referring to FIG. 8, in a semiconductor package 2000 according to the present embodiment, an interposer substrate ITP may be disposed on a package substrate PCB. In an embodiment, the package substrate PCB may be a double-sided or multi-layer printed circuit board. In an embodiment, the interposer substrate ITP may be formed of or include silicon. A first chip structure CH1 and a second chip structure CH2 may be arranged side by side in the first direction X, on the interposer substrate ITP. The interposer substrate ITP may include internal interconnection lines connecting the first chip structure CH1 to the second chip structure CH2.

The first chip structure CH1 may be connected to the interposer substrate ITP by the first outer connection members SB1. The first chip structure CH1 may be the same as or similar to the semiconductor packages 1000 to 1003 described with reference to FIGS. 1A to 7.

The second chip structure CH2 may be an application specific integrated circuit chip or a system-on-chip. The second chip structure CH2 may be referred to as a host or an application processor (AP). Alternatively, the second chip structure CH2 may be a semiconductor chip that is the same as or similar to the first chip structure CH1. The second chip structure CH2 may be connected to the interposer substrate ITP by second outer connection members SB2.

The interposer substrate ITP may be bonded to the package substrate PCB by third outer connection members SB3. Fourth outer connection members SB4 may be bonded to a bottom surface of the package substrate PCB. The outer connection members SB1 to SB4 may include at least one of copper bumps, copper pillars, or solder balls. Under-fill patterns UF1 to UF3 may be respectively provided to fill spaces between the first chip structure CH1 and the interposer substrate ITP, between the second chip structure CH2 and the interposer substrate ITP, and between the interposer substrate ITP and the package substrate PCB. The under-fill patterns UF1 to UF3 may be formed by a dispensing process and a curing process. The under-fill patterns UF1 to UF3 may be formed of or include an epoxy resin and may protect the outer connection members SB1 to SB3.

In a semiconductor package according to an embodiment of the disclosure, by forming a trench to penetrate a top surface of a dummy die, it may be possible to reduce the stiffness of the dummy die and thereby to bond the dummy die to stacked semiconductor dies more tightly or closer. This may make it possible to effectively remove a void, which may be formed between the dummy die and the semiconductor dies. As a result, the semiconductor package may be provided to have high durability and high reliability.

While example embodiments of the disclosure have been particularly shown and described, one of ordinary skill in the art that variations in form and detail may be made therein without departing from the spirit and scope of the attached claims.

What is claimed is:

1. A semiconductor package comprising:
a buffer die;
a plurality of semiconductor dies on the buffer die;
a dummy die on the plurality of semiconductor dies; and
a mold layer surrounding the buffer die, the plurality of semiconductor dies, and the dummy die,
wherein the dummy die comprises:
a dummy substrate comprising a trench formed in a top surface of the dummy substrate, extended in a first direction and a second direction, and having a shape of checkerboard; and
an oxide layer on a bottom surface of the dummy substrate,
wherein at least one of the plurality of semiconductor dies comprises:
a substrate,
an upper passivation layer on a top surface of the substrate, and
a lower passivation layer on a bottom surface of the substrate,
wherein the oxide layer is in direct contact with the upper passivation layer of an uppermost one of the plurality of semiconductor dies, and
wherein a level of a bottom surface of the trench is higher than a level of the bottom surface of the dummy substrate.

2. The semiconductor package of claim 1, wherein the buffer die comprises:
a first substrate;
first upper conductive pads on a top surface of the first substrate; and
first lower conductive pads on a bottom surface of the first substrate, wherein the at least one of the plurality of semiconductor dies comprises:
second upper conductive pads on a top surface of the substrate; and
second lower conductive pads on a bottom surface of the substrate,
wherein the first upper conductive pads are in contact with the second lower conductive pads of a lowermost one of the plurality of semiconductor dies, respectively, and
wherein the first upper conductive pads and the second lower conductive pads are formed of a same material.

3. The semiconductor package of claim 1, wherein the at least one of the plurality of semiconductor dies comprises:
second upper conductive pads on a top surface of the substrate; and
second lower conductive pads on a bottom surface of the substrate,
wherein the second upper conductive pads of a lower die of the plurality of semiconductor dies are in contact with the second lower conductive pads of an upper die of the plurality of semiconductor dies, respectively, and
wherein the second upper conductive pads and the second lower conductive pads are formed of the same material.

4. The semiconductor package of claim 1, wherein the buffer die comprises a first penetration via,
wherein the at least one of the plurality of semiconductor dies further comprises a second penetration via penetrating the substrate, and
wherein the first penetration via and the second penetration via are connected to each other.

5. The semiconductor package of claim 1, wherein the bottom surface of the trench is flat.

6. The semiconductor package of claim 1, wherein the bottom surface of the trench is concave.

7. The semiconductor package of claim 1, further comprising a heat transfer member configured to fill the trench.

8. The semiconductor package of claim 1, wherein the trench is filled with the mold layer.

9. The semiconductor package of claim 1, wherein the dummy die has a thickness ranging from about 55 μm to about 550 μm.

10. A semiconductor package comprising:
a buffer die;
a plurality of memory dies on the buffer die;
a dummy die on the plurality of memory dies; and
a mold layer surrounding the buffer die, the plurality of memory dies, and the dummy die,
wherein the buffer die comprises:
a first substrate;
first upper conductive pads on a top surface of the first substrate;
first lower conductive pads on a bottom surface of the first substrate; and
a first penetration via penetrating the first substrate,
wherein at least one of the plurality of memory dies comprises:
a second substrate;
second upper conductive pads on a top surface of the second substrate;
second lower conductive pads on a bottom surface of the second substrate; and
a second penetration via penetrating the second substrate,
wherein the dummy die comprises:
a third substrate comprising a trench formed in a top surface of the third substrate, extended in a first direction and a second direction, and having a shape of checkerboard;
an oxide layer on a bottom surface of the third substrate; and
a heat transfer member filling the trench,
wherein the dummy die has a thickness ranging from about 55 μm to about 550 μm.

11. The semiconductor package of claim 10, wherein the first upper conductive pads are in contact with the second lower conductive pads of a lowermost one of the plurality of memory dies, respectively, and
wherein the first upper conductive pads and the second lower conductive pads are formed of a same material.

12. The semiconductor package of claim 10, wherein the second upper conductive pads of a lower die of the plurality of memory dies are in contact with the second lower conductive pads of an upper die of the plurality of memory dies, respectively, and
wherein the second upper conductive pads and the second lower conductive pads are formed of the same material.

13. The semiconductor package of claim 10, wherein the at least one of the plurality of memory dies further comprises:
an upper passivation layer on the top surface of the second substrate, and
a lower passivation layer on the bottom surface of the second substrate, and
wherein the oxide layer of the dummy die is in direct contact with the upper passivation layer of an uppermost one of the plurality of memory dies.

14. The semiconductor package of claim 10, wherein the trench has a flat bottom surface.

15. The semiconductor package of claim 10, wherein the trench has a concave bottom surface.

16. The semiconductor package of claim 10, wherein a bottom surface of the trench is located at a level that is higher than the bottom surface of the third substrate.

17. A semiconductor package comprising:
a package substrate;
an interposer substrate on the package substrate;
a first semiconductor chip on the interposer substrate; and
a second semiconductor chip on the interposer substrate,
wherein the first semiconductor chip comprises:
a buffer die;
a plurality of semiconductor dies on the buffer die;
a dummy die on the plurality of semiconductor dies; and
a mold layer surrounding the buffer die, the plurality of semiconductor dies, and the dummy die,
wherein the dummy die comprises:
a dummy substrate comprising a trench formed in a top surface of the dummy substrate, extended in a first direction and a second direction, and having a shape of checkerboard;
a heat transfer member filling the trench; and
an oxide layer on a bottom surface of the dummy substrate,
wherein at least one of the plurality of semiconductor dies comprises a substrate,
wherein a level of a bottom surface of the trench is higher than a level of the bottom surface of the dummy substrate, and
wherein the bottom surface of the trench is flat.

18. The semiconductor package of claim 17, wherein the at least one of the plurality of semiconductor dies comprises:
an upper passivation layer on a top surface of the substrate; and
a lower passivation layer on a bottom surface of the substrate,
wherein the oxide layer of the dummy die is in direct contact with the upper passivation layer of an uppermost one of the plurality of semiconductor dies.

19. The semiconductor package of claim 17, wherein the at least one of the plurality of semiconductor dies comprises:
upper conductive pads on a top surface of the substrate; and
lower conductive pads on a bottom surface of the substrate,
wherein the upper conductive pads of a lower die of the plurality of semiconductor dies are in contact with the lower conductive pads of an upper die of the plurality of semiconductor dies, respectively, and
wherein the upper conductive pads and the lower conductive pads are formed of the same material.

20. The semiconductor package of claim 17, wherein the dummy die has a thickness ranging from about 55 μm to about 550 μm.
